(19) United States
(12) Patent Application Publication
(10) Pub. No.: US 2012/0193126 A1
(43) Pub. Date: Aug. 2, 2012

(54) METHOD OF FORMING SENSORS AND CIRCUITS ON COMPONENTS

(75) Inventors: Kathleen Blanche MOREY, Schenectady, NY (US); Yuk-Chiu LAU, Schenectady, NY (US); Jon Conrad SCHAEFFER, Greenville, SC (US); Joshua Lee MARGOLIES, Schenectady, NY (US)

(73) Assignee: GENERAL ELECTRIC COMPANY, Schenectady, NY (US)

(21) Appl. No.: 13/017,628

(22) Filed: Jan. 31, 2011

(51) Int. Cl. H05K 1/00; B05D 1/02; H05K 1/16; B05D 3/02; B05D 3/06; B05D 5/12; B05D 1/36

(52) U.S. Cl. 174/251; 427/123; 427/597; 427/98.4; 174/260

(57) ABSTRACT

A method for depositing a powder metal onto a surface of the substrate and a substrate with conductive elements provided on a surface of the substrate are disclosed. The conductive elements are formed by cold spray depositing at least one layer of powder metal onto the surface of the substrate to form at least one conductive element on the surface of the article.

### FIELD OF THE INVENTION

The present disclosure is directed to a method for using cold spray technology to form sensors and circuits on surfaces of an article or component.

### BACKGROUND OF THE INVENTION

There exist several methods for providing sensors and circuits in turbine components and other similar devices. One such method includes machining channels into which the necessary wiring is embedded. Other methods include producing the sensors and circuits on the coated surface of the components. Approaches include additive fabrication through screen printing of conductive ink-pastes followed by a thermal curing step; direct writing of conductive pastes through micro-dispensing systems; plasma spray deposition; laser-based methods based on material removal for feature fabrication; and various combinations of these methods.

In many applications, the substrate or the electronic materials used to produce the sensors or circuits cannot be exposed to excessive temperatures, as needed by some traditional sensor fabrication processes—for example, those involving a firing step. Therefore, the concept of direct write patterning is increasingly used. There are advantages to direct write fabrication of metallic circuits through all-additive approaches. These include the ability to rapidly print patterns for circuit prototyping by translating CAD objects to manufactured components; the ability to write on conformal geometries; part-to-part customizability; simple and straightforward design changes; minimizing material waste through focused patterning; and reduced environmental issues through elimination of etching chemicals, solvents, and subtraction-processed waste material. Many present direct write methods, however, have the disadvantage that it is necessary to thermally cure the printed paste to achieve the requisite conductivity or other functional properties.

Thermal spray is a directed spray process or method in which material, generally in molten, semi-molten, or solid form, is accelerated to high velocities, and then impinges upon a substrate, where a dense and strongly adhered deposit is rapidly built. Material is typically injected in the form of a powder, wire or rod into a high velocity combustion or thermal plasma flame, which imparts thermal and momentum transfer to the particles. By carefully controlling the plume characteristics and material state, it is possible to deposit a vast range of materials (metals, ceramics, polymers and combinations thereof) onto virtually any substrate in various conformal shapes. For metals, the particles can be deposited in solid or semi-solid state. For ceramic deposits, it is generally necessary to bring the particles to well above the melting point, which is achieved by either a combustion flame or a thermal plasma arc. The deposit is built up by successive impingement of droplets, which yield flattened, solidified platelets, referred to as ‘splats’. The deposited microstructure and, thus, properties, aside from being dependent on the spray material, depend strongly on the processing parameters, which can be numerous and complex. Thermal spray processes may also cause compositional changes, which may make that process not very attractive for direct-writing sensors if the specific composition is very important. In addition, the thermal stresses and gradients imparted to the component from the thermal spray process may limit the types of components that can be applied.

Cold spray deposition or technology and related solid state kinetic energy processes are a new family of spray devices. These systems, through special convergent/divergent nozzles, use continuous gas pressure to accelerate a variety of materials to supersonic velocities to impact onto metallic and ceramic substrates where an unusually high adhesive bond is achieved, thereby depositing he material onto the substrate. This unique process can produce a fully dense (minimal porosity) deposit at much lower gas temperatures (such as, for example, at less than or equal to 1000° C.) and component temperatures (such as, for example, approximately 200° C.). Generally, cold spray technology is not directed to direct write methods.

Therefore, a method to deposit metals and alloys on a substrate without compositional changes typically associated with high heat input processes would allow the deposits to act as sensors and circuits and a process such as this would be desirable in the art.

### BRIEF DESCRIPTION OF THE INVENTION

One method for depositing a powder metal onto a surface of an article includes: providing the article, and cold spray depositing at least one layer of powder metal onto the surface of the article to form at least one conductive element on the surface of the article.

One method for writing of a conductive element onto a surface of a substrate includes: producing a mixture of a metal powder and a gas; accelerating the mixture through a nozzle of a spray gun; and directing the mixture onto the surface of the substrate in a predetermined pattern for forming the conductive element.

One embodiment includes a substrate with at least one conductive element provided on a surface of the substrate. The at least one conductive element is formed of powder metal deposited onto the surface by cold spraying. The at least one conductive element is embedded on the surface of the substrate.

Other features and advantages will be apparent from the following more detailed description of the embodiments, taken in conjunction with the accompanying drawings which illustrate.

### BRIEF DESCRIPTION OF THE DRAWINGS

FIG. 1 is a diagrammatic representation of an apparatus for depositing cold sprayed powder metal materials onto a substrate; and

FIG. 2 is a schematic top view of a substrate with conductive circuits sprayed thereon.

### DETAILED DESCRIPTION OF THE INVENTION

The disclosure relates to a method of using cold spray technology to spray and form ductile, continuous conductive circuits or pathways on substrates, components or articles, such as, but not limited to, turbine components, compressor sections and rotor wheels. The conductive circuits or pathways can be used to produce and/or connect a variety of sensors—for example, thermistors, thermocouples, thermopiles, temperature sensors, displacement sensors, strain sensors, magnetic sensors, humidity sensors, gas sensors, flow sensors, heat flux sensors, and/or other sensors for monitoring the articles' conditions in-situ, as well as monitoring system performance. In applications in which the materials used for the conductive pathways are not inherently ductile, the method may include localized improvements to cold-sprayed deposited materials, such as by raising the temperature of the deposited material high enough for short durations to recover ductility without significant heat input to the substrate or any underlying prior cold-sprayed deposits or coatings.

In general, cold spray process for depositing powder metal materials onto a surface of the substrate is advantageous in that it provides sufficient energy to accelerate particles to high enough velocities such that, upon impact, the particles plastically deform and bond to the surface or onto a previously deposited layer. The process allows the build-up of a relatively dense coating or structural deposit. As is known in the art, cold spray does not metallurgically transform the particles from their solid state.

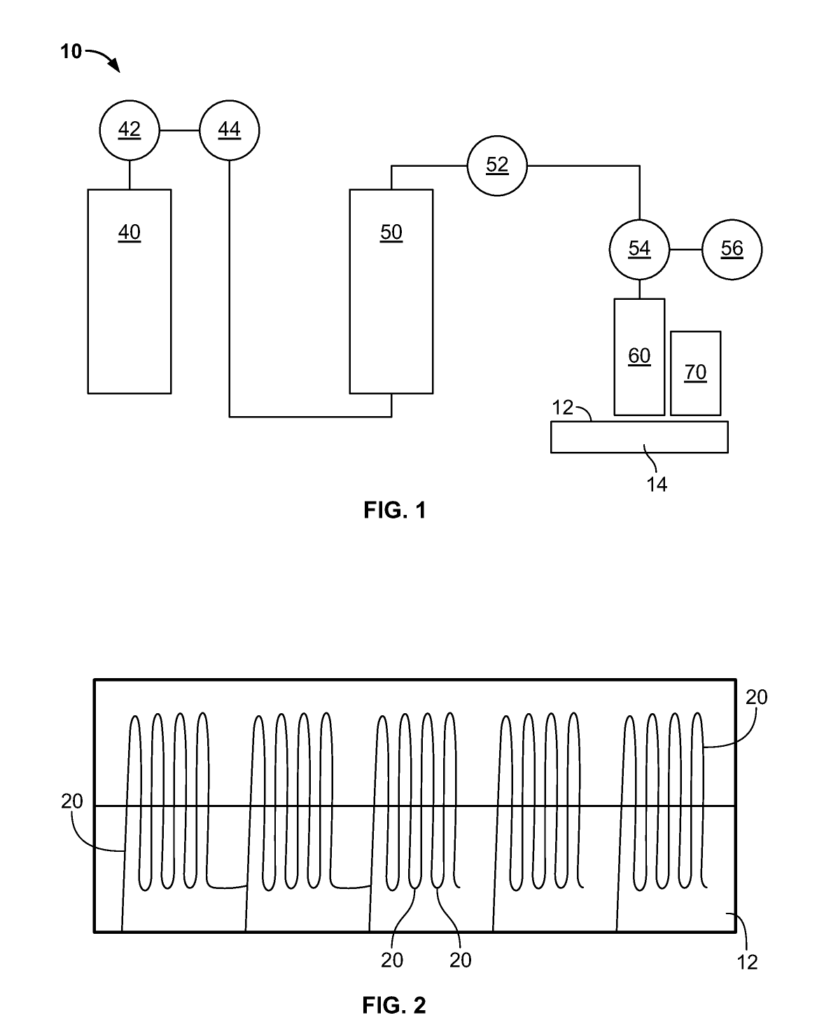

Referring now to FIG. 1, there is shown a diagrammatic view of a system 10 for depositing a material, such as powder metal, onto a surface 12 of a substrate or article 14 to form conductive elements 20 (as shown in FIG. 2), such as pathways or sensors. The system 10 includes a process gas tank 40 which is connected to a powder hopper assembly 50. Any known process gas tank and powder hopper assembly which have the appropriate specifications may be used. A regulator 42 and shut-off valve 44 are positioned between the tank 40 and assembly 50 to monitor and control the flow of the process gas to the assembly 50. The assembly 50 is connected to a spray gun 60. The spray gun has a converging/diverging nozzle through which the powder metal material supplied from the assembly 50 is accelerated and sprayed onto the surface 12 of the article or substrate 14. A shut-off valve 52, tee member 54 and needle bypass valve 56 are positioned between the assembly 50 and the spray gun 60 to control the flow of the powder metal material to the spray gun 60. The substrate or article 14 may be held stationary or may be articulated, rotated, or translated by any suitable means (not shown) known in the art.

The powdered metal material may be of the same composition as the article 14 or it may be a compatible composition. For example, the powder metal material may be a nickel-based alloy, a copper-based alloy or an aluminum-based alloy. One example of the powdered metal material that may be used to form the deposit on the surface 12 is copper with a diameter in the range of from about 1 micron to about 50 microns or, more specifically from about 1 micron to about 10 microns, and all subranges therebetween or from about 1 micron to 20 microns or, more specifically from about 1 micron to about 5 microns, and all subranges therebetween if the particles are spherical. In general, smaller particle sizes enable the achievement of higher particle velocities. The more narrow the particle size distribution, the more uniform the particle velocity.

The material particles to be deposited may be accelerated using compressed gas from the process gas tank 40, such as a gas selected from the group consisting of helium, nitrogen, another inert gas, and mixtures thereof. Helium produces the highest velocity due to its low molecular weight. Gas pressure is generally in the range of from about 200 psi to about 600 psi or, more specifically from about 200 psi to about 500 psi, and all subranges therebetween, depending on the powder metal material composition. In the exemplary embodiment described, about 300 psi is a suitable pressure.

The bonding mechanism employed in this process is strictly solid state, meaning that the particles plastically deform but do not melt. Any oxide layer that is formed on the particles, or is present on the surface 12, or is present in a previously deposited layer, is broken up and fresh metal-to-metal contact is made at very high pressures.

The process gas is may be heated so that gas temperatures are in the range of from about 60 degrees Fahrenheit to about 2000 degrees Fahrenheit or, more specifically from about 600 degrees Fahrenheit to about 1200 degrees Fahrenheit, and all subranges therebetween. If desired, the main gas may be heated as high as about 100 degrees Fahrenheit to about 1200 degrees Fahrenheit depending on the material being deposited. Any suitable means known in the art may be used to heat the gas.

To deposit the powdered metal material to form the conductive elements 20, the spray gun 60 may pass over the surface 12 of the article 14 multiple times. The number of passes is a function of the thickness of the material to be applied. The process described herein is capable of forming a deposit having any desired thickness. Cold spray can produce thin layers ranging from about 10 microns to about 100 microns per single pass or, more specifically from about 25 microns to about 50 microns and all subranges therebetween. The conductive elements 20 may be formed of conductive metallic lines, spots, areas, and vias (e.g., filled holes).

The velocity of the powdered metal particles leaving the nozzle of the spray gun 60 may be in the range of from about 600 m/s to about 1500 m/s or, more specifically from about 850 m/s to about 1200 m/s and all subranges therebetween. The nozzle of the spray gun 60 is held at a distance from the surface 12. This distance is known as the spray distance and may be in the range of from about 1 mm to about 75 mm or, more specifically from about 25 mm to about 50 mm and all subranges therebetween. By controlling the distance, the issue of gas stream divergence at the tube exit can be controlled. Gas stream divergence increases as the distance from the exit is increased. By controlling the distance that the nozzle of the spray gun 60 is held from the surface 12 of the article 14, a desirable deposit profile can be obtained.

As previously described, the powdered metal material may be deposited onto the surface 12 so as to form a conductive pathway having one or more layers. It has been discovered that the deposited layer(s) could receive localized improvements from laser processing. With proper settings, a laser could be passed directly over a deposited layer to improve density (sintering) and/or raise the material temperature high enough, for a short duration, to recover ductility without significant heat input to the material or underlying, prior cold-sprayed layer or article 14. To this end, the system 10 includes a laser 70 which may be movable to allow the laser beam to apply heat to the entire powder metal material deposit. The laser 70 may comprise any suitable laser known in the art. The laser processing may be performed after each successive cold-sprayed layer deposit.

The laser 70 may be mounted to the nozzle of the spray gun 60, if desired, so that the laser 70 moves with the nozzle of the spray gun 60. Such a laser would track along the spray beam while locally enhancing the deposit (in situ heat treatment).

Cold spray is most effective in depositing ductile materials. It has been shown that additional heat input can widen the range of material that can be successfully deposited with cold spray. The use of the laser 70 provides the heat input necessary to help deposit materials of a less ductile nature. In addition, the use of the laser can provide external heat which can also increase the density or reduce the porosity of deposited material.

Whether a laser is used or not, the deposited or embedded conductive elements 20 can be overcoated with protective coating, allowing applications in harsh environments.

The deposited or embedded conductive elements 20 deliver real time telemetry. This provides closed-loop feedback which allows the system in which the article 14 is provided to operate at peak efficiency. In addition, the fidelity of the data collected through the conductive elements 20 would be representative of the article 14 and system, as the conductive elements are directly deposited, thereby eliminating interfaces and other areas of interference associated with known sensors.

The cold spray process offers many advantages over other metallization processes. Since the powders are not heated to high temperatures, no oxidation, decomposition, or other degradation of the feedstock materials occurs. Powder oxidation during deposition is also controlled, since the particles are contained within the oxygen-free accelerating gas stream. Other potential advantages include the formation of compressive residual surface stresses and retaining the microstructure of the feedstock. Because the feedstock is not melted, cold spray offers the ability to deposit materials that cannot be sprayed conventionally due to the formation of brittle intermetallics or a propensity to crack upon cooling or during subsequent heat treatments. Stresses associated with thermal mismatch are, therefore, eliminated.

As described herein, cold spray technology is used to spray ductile (metallic) conductive elements 20 on the surface of the article for the fabrication of electronics and sensors directly on the surface. The material may be deposited without the need for pre-processing or post-processing steps such as grit blasting, annealing or heat treating, although these processes can be performed if desired. As the deposition of the material is controlled, and as the material properties are not degraded during processing, this direct writing process can be used to fabricate a variety of sensors and other electronic structures--for example, thermistors, thermocouples, thermopiles, strain sensors, magnetic sensors, humidity sensors, gas sensors, flow sensors, heat flux sensors, etc. The ability to deposit materials with no compositional change typically associated with thermal spray processing allows the materials to have the complex chemistry needed for the conductive elements 20 (alumel, chromel, constantan, Pt/Rh, etc.), thereby allowing the conductive elements to have properties consistent with conventional wired elements.

Furthermore, these conductive elements 20 are deposited or embedded on a surface of an article during manufacture to provide an extremely robust, long-life sensing and monitoring system for the article or device, which is superior to known sensors that are positioned in machined trenches and are attached manually using adhesives or other post-manufacturing techniques. The conductive elements 20 disclosed remain full-life with the article (i.e. the life of the conductive elements 20 is consistent with the article 14 and system), as opposed to the conventional sensors which must be removed and/or serviced earlier than the service cycle for the associated article.

Also, because the material can be layered, this process can be used to fabricate three-dimension sensors, e.g., multi-layer sensors on the same surface area footprint. This allows for novel sensor and electronic devices to be prepared in-situ and in environmentally-friendly lean manufacturing methods. A sensor that is directly embedded into the article also has substantial advantages in terms of reliability and longevity.

In many remote sensor-monitoring situations, wireless concepts are required since access is not easy. For active wireless systems, local power is desirable to drive the circuit. One way to obtain this power—for example, in hot component monitoring—is power harvesting through thermo-piles, which is an extension to thermocouple technology.

Other advantages of direct write cold spray technology for sensor fabrication include, for example, robust sensors integrated directly into coatings, thus providing improved coating-performance monitoring, high-throughput manufacturing and high-speed direct write capability, and useful electrical and mechanical properties in the as-deposited state. In some cases, the properties can be further enhanced by appropriate laser treatment. Further advantages include being cost-effective, efficient, and able to process in virtually any environment. The method is robotics-capable for difficult-to-access and severe environments, and can be applied on a wide range of substrates and conformal shapes. The method is also able to be used with new or existing parts, without the need for specialized equipment or planning.

While the disclosure has been described with reference to an embodiment, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

1. A method for depositing a powder metal onto a surface of an article, the method comprising the steps of:
providing the article;
cold spray depositing at least one layer of powder metal onto the surface of the article to form at least one conductive element on the surface of the article.

2. The method according to claim 1, including the step of positioning a nozzle of a spray gun proximate to the surface of the article to control the divergence of the cold spray deposits which form the at least one conductive element.

3. The method according to claim 2, wherein the nozzle of the spray gun is positioned a distance from about 1 mm to about 75 mm from the surface of the article.

4. The method according to claim 1, including the step of applying heat for a short duration to the at least one layer of powder metal to recover ductility of the at least one layer of powder metal.

5. The method according to claim 4, wherein the step of applying heat comprises providing a laser to apply the heat to the at least one layer of powder metal to recover ductility of the at least one layer of powder metal.

6. The method according to claim 5, wherein the laser is attached to a nozzle of a spray gun which performs the cold spray depositing.

7. The method according to claim 1, wherein said cold spray depositing step comprises cold spray depositing multiple layers of powder metal.

8. The method according to claim 7, including a step of applying heat for a short duration to the each multiple layer of powder metal after each multiple layer is cold spray deposited, thereby recovering ductility of each multiple layer of powder metal.

9. The method according to claim 7, including a step of applying heat for a short duration to the multiple layers of powder metal after the multiple layers are cold spray deposited.

10. The method according to claim 1, including a step of overcoating the at least one conductive element with a protective coating.

11. A method for writing of a conductive element onto a surface of a substrate, the method comprising:
producing a mixture of a metal powder and a gas;
accelerating the mixture through a nozzle of a spray gun;
directing the mixture onto the surface of the substrate in a predetermined pattern for forming the conductive element.

12. The method according to claim 11, wherein the conductive element is a sensor.

13. The method according to claim 11, wherein the conductive element is a circuit.

14. The method according to claim 11, including a step of positioning the nozzle of a spray gun proximate to the surface of the substrate to control divergence of the mixture which forms the conductive element.

15. The method according to claim 14, wherein the nozzle of the spray gun is positioned a distance from about 1 mm to about 75 mm from the surface of the substrate.

16. The method according to claim 11, including applying heat for a short duration to the mixture as it is directed onto the surface of the substrate to recover ductility of the mixture.

17. The method according to claim 16, wherein a laser is provided to apply the heat to the mixture as it is directed onto the surface of the substrate.

18. A substrate comprising:
at least one conductive element provided on a surface of the substrate, the at least one conductive element being formed of powder metal deposited onto the surface by cold spraying;
the at least one conductive element being embedded on the surface of the substrate.

19. The substrate according to claim 18, wherein the at least one conductive element is a sensor.

20. The substrate according to claim 18, wherein the at least one conductive element is a circuit.
